(19) United States
(12) Patent Application Publication
(10) Pub. No.: US 2020/0328078 A1
(43) Pub. Date: Oct. 15, 2020

(54) INTEGRATED IN-SITU DRY SURFACE PREPARATION AND AREA SELECTIVE FILM DEPOSITION

(71) Applicant: Tokyo Electron Limited, Tokyo (JP)

(72) Inventor: Kandabara Tapily, Albany, NY (US)

(21) Appl. No.: 16/846,219

(22) Filed: Apr. 10, 2020

Related U.S. Application Data
(60) Provisional application No. 62/832,884, filed on Apr. 12, 2019.

(51) Int. Cl. H01L 21/02; C23C 16/02; C23C 16/455

(52) U.S. Cl. CPC H01L 21/02301; H01L 21/02304; H01L 21/02211; H01L 21/02164; C23C 16/45536; H01L 21/02189; H01L 21/02178; H01L 21/0228; C23C 16/0227; H01L 21/02181

(57) ABSTRACT

A method and processing system for integrated in-situ dry surface preparation and area selective film deposition. The method includes providing a substrate having a first film and a second film, the first and second films containing different materials, and performing sequential dry processing steps at sub-atmospheric pressure, the steps including: a) treating the substrate to remove residue from the first and second films, b) exposing the substrate to an oxygen-containing gas to functionalize a surface of the first film, c) exposing the substrate to a reactant gas that selectively forms a blocking layer on the first film or the second film, and d) selectively depositing a material film on the first film or the second film not containing the blocking layer by exposing the substrate to a deposition gas. Steps a)-c) or a)-d) may be performed without exposing the substrate to air at any time.

### CROSS-REFERENCE TO RELATED APPLICATIONS

This application is related to and claims priority to U.S. Provisional Patent Application Ser. No. 62/832,884 filed on Apr. 12, 2019, the entire contents of which are herein incorporated by reference.

### FIELD OF THE INVENTION

The present invention relates to semiconductor processing, and more particularly, to integrated in-situ dry surface preparation and area selective film deposition.

### BACKGROUND OF THE INVENTION

As device size is getting smaller, the complexity in semiconductor device manufacturing is increasing. The cost to produce the semiconductor devices is also increasing and cost effective solutions and innovations are needed. As smaller transistors are manufactured, the critical dimension (CD) or resolution of patterned features is becoming more challenging to produce. Selective deposition of thin films is a key step in patterning in highly scaled technology nodes. New deposition methods are required that provide selective film deposition on different material surfaces.

### SUMMARY OF THE INVENTION

A method for integrated in-situ dry surface preparation and area selective film deposition. The method includes providing a substrate having a first film and a second film, where the first and second films contain different materials, and performing sequential dry processing steps at sub-atmospheric pressure, the steps including: a) treating the substrate to remove residue from the first and second films, b) exposing the substrate to an oxygen-containing gas to functionalize a surface of the first film, c) exposing the substrate to a reactant gas that selectively forms a blocking layer on the first film or the second film, and d) selectively depositing a material film on the first film or the second film not containing the blocking layer by exposing the substrate to a deposition gas. In one embodiment, steps a)-c) are performed without exposing the substrate to air at any time during or between the steps. In another embodiment, steps a)-d) are performed without exposing the substrate to air at any time during or between the steps.

A processing system for integrated in-situ dry surface preparation and area selective film deposition is described.

### BRIEF DESCRIPTION OF THE DRAWINGS

A more complete appreciation of embodiments of the invention and many of the attendant advantages thereof will become readily apparent with reference to the following detailed description, particularly when considered in conjunction with the accompanying drawings, in which:

FIG. 1 is a process flow diagram for a method of integrated in-situ dry surface preparation and area selective film deposition according to an embodiment of the invention;

FIGS. 2A-2F show schematic cross-sectional views of a method of integrated in-situ dry surface preparation and area selective film deposition according to an embodiment of the invention; and

FIG. 3 schematically shows arrangements of processing chambers in a processing system for performing integrated in-situ dry surface preparation and area selective film deposition according to an embodiment of the invention.

### DETAILED DESCRIPTION OF SEVERAL EMBODIMENTS

A method is provided for integrated in-situ dry surface preparation and area selective film deposition. The method includes performing sequential dry processing steps at sub-atmospheric pressure that include pre-cleaning processes without exposure to air/breaking vacuum to improve formation of a blocking layer on a non-growth surface and enhance subsequent area selective film deposition on a growth surface. Embodiments of the invention may be applied to surface sensitive deposition processes such as atomic layer deposition (ALD), and chemical vapor deposition (CVD), and spin-on deposition. This improved selectivity provides an improved margin for line-to-line breakdown and electrical leakage performance in the semiconductor device containing the metal layer surface.

A partially manufactured semiconductor substrate commonly contains a variety of surface defects that can affect area selective deposition of films on the substrate. In one example, surface preparation under tightly controlled and clean vacuum conditions is critical to achieve a highly ordered or dense blocking layer on a non-growth surface that enables subsequent selective film deposition on a growth surface.

In one example, after a chemical mechanical planarization (CMP) process, a substrate surface contains residues and impurities formed by the CMP process. A common residue includes benzotriazine (BTA) which is a chemical agent widely used in the CMP process. The impurities may include diffused/migrate metal impurities from a metal line to a dielectric material surface. Also, a planarized metal surface on the substrate may be oxidized by the CMP slurry and atmospheric exposure. In one example, a copper oxide layer may be formed on a planarized copper metal interconnect line.

Some embodiments of the invention provide methods for effective surface pre-treatment for selectively depositing metal oxide or Sift films on dielectric material surfaces relative to metal surfaces. The selective deposition is achieved by providing long incubation times on metal layer surfaces that contain a blocking layer, while providing fast and effective deposition on dielectric material surfaces where film deposition is desired.

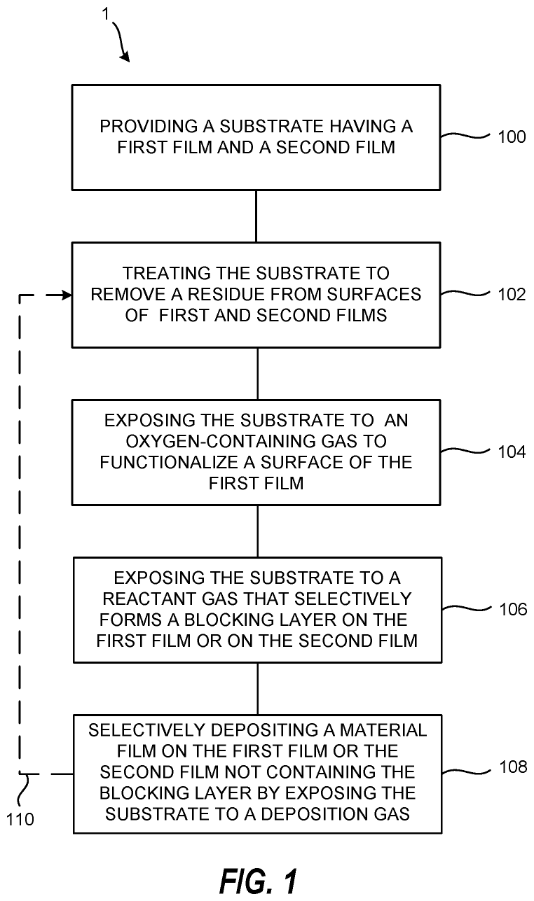

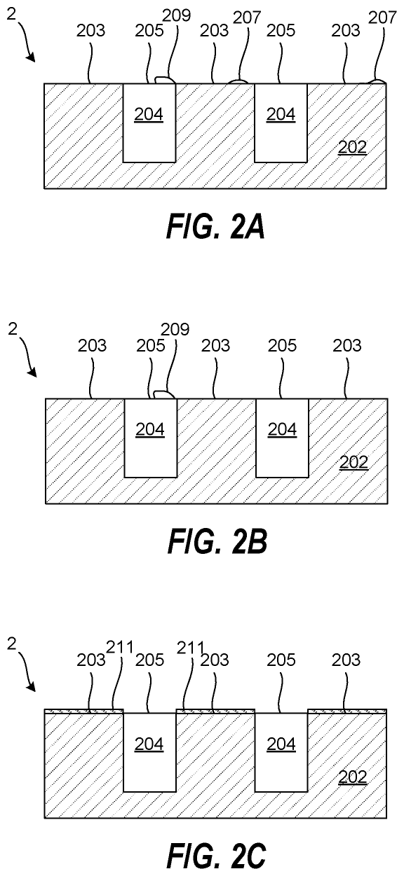

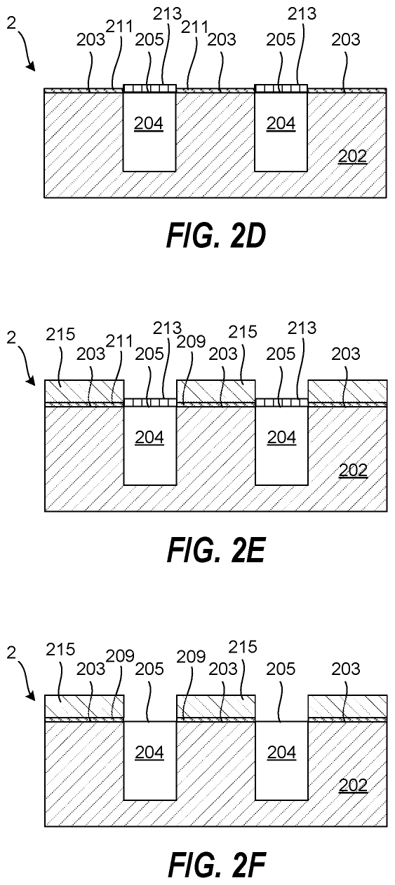

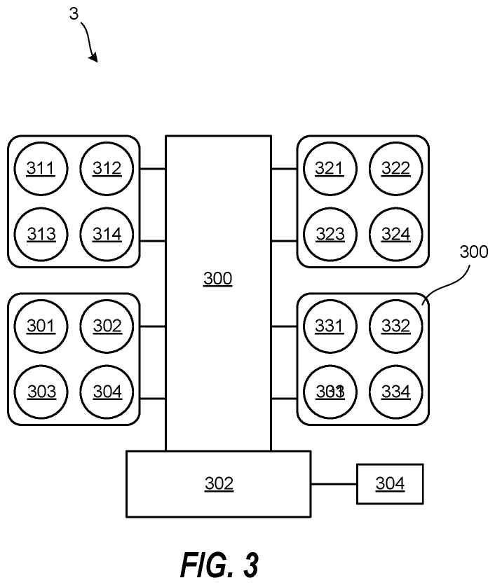

Referring now to FIGS. 1 and 2A-2F, the process flow diagram 1 includes, in 100, providing a substrate 2 into a processing system containing a plurality of processing chambers. The substrate 2 includes a first film 202 having a surface 203 and a second film 204 having a surface 205, where the first film 202 and the second film 204 contain different materials. According to one embodiment, the first film 202 contains a dielectric material and the second film 204 contains a metal layer or a Si layer. The dielectric material can, for example, contain SiO₂, SiOH, SiOC, a pre-metal dielectric (PMD), or a metal-containing dielectric material. In one example, the metal-containing dielectric material can contain a metal oxide, a metal nitride, or a metal oxynitride. In some examples, the metal layer can contain Cu, Al, Ta, Ti, W, Ru, Co, Ni, or Mo. The Si layer can include poly-silicon or amorphous silicon. FIG. 1A further shows an organic residue 207 and impurity 209 formed on the substrate 2.

The process flow 1 includes performing integrated dry processing at sub-atmospheric pressure in the processing tool that includes, in 102, treating the substrate 2 in a first plurality of process chambers to remove a residue 207 from surfaces of the substrate 2. This is schematically shown in FIG. 2B. The treating can include heat-treating the substrate 2, exposing the substrate 2 to a cleaning gas containing forming gas (H₂ and N₂), exposing the substrate 2 to plasma excited H₂ gas, or a combination thereof in any sequence. The heat-treating may be performed under high vacuum conditions or in the presence of an inert gas. In another embodiment, the treating can be thermally-based and/or plasma-based and can include exposure to H₂, Ar, NH₃, O₂, or a combination thereof. The plasma-excited species can be very low energy species in order to reduce plasma damage of the substrate 2. The plasma-excited species may be generated using different plasma sources, for example a microwave plasma source, an inductively couple plasma (ICP) source, a capacitively coupled plasma (CCP) source, or a very high frequency (VHF) plasma source.

The treating can additionally chemically reduce diffused/migrate metal impurities from the second film 204 to the first film 202. Once example is CuOₓ diffusion to the dielectric area due to long queue time in air.

The process flow further includes, in 104, exposing the substrate 2 to an oxygen-containing gas in a second plurality of process chambers to functionalize the surface 203 of the first film 202 and remove the impurity 209 from the substrate 2. FIG. 2C shown a functionalized layer 211 on the surface 203. In one embodiment, the oxygen-containing gas can include isopropyl alcohol (IPA), ethanol or other alcohols. IPA is a mild oxidant and restores hydroxyl groups (—OH) on the surface 203 (e.g., a dielectric material surface) without oxidizing the surface 205 (e.g., a metal surface). In one embodiment, the exposure to the oxygen-containing gas may be performed in the first processing chamber.

The process flow further includes, in 106, exposing the substrate 2 to a reactant gas in a third plurality of process chambers that selectively form a blocking layer on the first film 202 or on second film 204. A blocking layer 213 that is selectively formed on the second film 204 is schematically show in FIG. 2D. In one example, the reactant gas contains a molecule that is capable of forming self-assembled monolayers (SAMs) on the substrate 2. SAMs are molecular assemblies that are formed spontaneously on substrate surfaces by adsorption and are organized into more or less large ordered domains. The SAMs can include a molecule that possesses a head group, a tail group, and a functional end group, and SAMs are created by the chemisorption of head groups onto the substrate from the vapor phase at room temperature or above room temperature, followed by a slow organization of the tail groups. Initially, at small molecular density on the surface, adsorbate molecules form either a disordered mass of molecules or form an ordered two-dimensional “lying down phase”, and at higher molecular coverage, over a period of minutes to hours, begin to form three-dimensional crystalline or semicrystalline structures on the substrate surface. The head groups assemble together on the substrate, while the tail groups assemble far from the substrate. The reactant gas and the SAMs are selected according to whether it is desired to form the blocking layer 213 on the second film 204 or on the first film 202. The head group of the molecule forming the SAMs can include a thiol (R—SH), a silane, an alkene (R—C═C), an alkanoic acid (R—COOH), or a phosphonic acid (R—PO₃H₃). Examples of silanes include molecule that include C, H, Cl, F, and Si atoms, or C, H, Cl, and Si atoms. Non-limiting examples of the molecule include perfluorodecyltrichlorosi lane (CF₃(CF₂)₇CH₂CH₂SiCl₃), perfluorodecylmonochlorosilane, perfluorodecanethiol (CF₃(CF₂)₇CH₂CH₂SH), octadecylthiol, chlorodecyldimethylsilane (CH₃(CH₂)₈CH₂Si(CH₃)₂Cl), or tertbutyl(chloro)dimethylsilane ((CH₃)₃CSi(Cl)(CH₃)₂)).

In one embodiment, where the second film 204 is a metal, a reactant gas containing a thiol may be selected to form the blocking layer 213 on the second film 204 but not on the first film 202 as shown in FIG. 2D. According to another embodiment, where the first film 202 is a dielectric material, a reactant gas containing a silane may be selected to form a blocking layer on the first film 202 but not on the second film 204.

According to one embodiment, steps 102, 104, and 106 may be performed without exposing the substrate 2 to air at any time during or between the steps. An exemplary processing system is shown in FIG. 3 that can perform steps 102, 104, and 106 without air exposure. Once the blocking layer 213 is formed on the substrate 2, a subsequent air exposure is not as critical as during or between steps 102, 104, and 106.

The process flow further includes, in 108, selectively depositing a material film 215 on the first film 202 or the second film 204 not containing the blocking layer 213 by exposing the substrate 2 to a deposition gas in a fourth plurality of process chambers. In the embodiment shown in FIG. 2E, the material film 215 is selectively deposited on the first film 202 but not on the second film 204 containing the blocking layer 213. In one example, the material film 215 may contain HfO₂, ZrO₂, SiO₂, TiO₂ or Al₂O₃ or a combination of thereof. In another example, the material film 215 may include a metal film or a metal-containing film such as TaN, TiN, Ru, or HfN. The material film 215 may, for example, be deposited by ALD or plasma-enhanced ALD (PEALD). In some examples, the material film 215 may be deposited by ALD using alternating exposures of a metal-containing precursor and an oxidizer (e.g., H₂O, H₂O₂, plasma-excited O₂ or O₃). According to one embodiment, steps 102-108 may be sequentially repeated at least once to increase a thickness of the material film 215 selectively deposited on the first film 202.

According to one embodiment, exposing the substrate to the deposition gas forms nuclei of the material film on the first or second film containing the blocking layer. The formation of the nuclei is due to imperfect deposition selectivity and the nuclei may be removed by etching to improve subsequent deposition selectivity.

According to another embodiment, the material film 215 may be a SiO₂ film that is selectively deposited on the first film 202. The selective SiO₂ deposition may be performed by exposing the substrate 2 to a metal-containing catalyst precursor, and thereafter, exposing the substrate to silanol gas. Examples of metal-containing catalyst precursors include aluminum (Al) and titanium (Ti). In one example, the metal-containing precursor can contain AlMe₃.

The metal-containing catalyst precursor forms a catalyst layer on the functionalized layer 211. The catalyst layer enables subsequent SiO₂ deposition using a deposition gas containing a silanol gas in the absence of any oxidizing and hydrolyzing agent. This catalytic effect can been observed until the SiO₂ film is a few nm thick, and thereafter the SiO₂ deposition automatically stops. In some examples, the deposition gas may further contain an inert gas such as Argon. In one embodiment, the deposition gas may consist of a silanol gas and an inert gas. In one example, the silanol gas may be selected from the group consisting of tris(tert-pentoxy) silanol, tris(tert-butoxy) silanol, and bis(tert-butoxy)(isopropoxy) silanol. The substrate temperature may be approximately 150° C., or less, during the exposing. In another example, the substrate temperature may be approximately 120° C., or less. In yet another example, the substrate temperature may be approximately 100° C., or less.

FIG. 3 schematically shows arrangements of processing chambers in a processing system for performing integrated in-situ dry surface preparation and area selective film deposition according to an embodiment of the invention. The processing system 3 includes multiple pluralities of different process chambers for performing high-throughput substrate processing under vacuum conditions. The processing system 3 includes a first plurality of process chambers 301-304 for gaseous removal of a residue from a substrate, a second plurality of process chambers 310-314 for gaseous functionalization of a film on the substrate, a third plurality of process chambers 320-324 for gaseous formation of a blocking layer on the substrate, and a fourth plurality of process chambers 330-334 for gaseous deposition of a material film on the substrate. The processing system 3 further includes a vacuum transfer chamber 300 connecting the first, second, third, and fourth plurality of process chambers 310-334, a substrate loading chamber 302, and a controller 304 that contains instructions for the integrated in-situ dry surface preparation and area selective film deposition. The instructions include removing the residue from the substrate in the first plurality of process chambers 301-304, transferring the substrate under vacuum conditions from the first plurality of process chambers 301-304 to the second plurality of process chambers 311-314, and functionalizing the film on the substrate in the second plurality of process chambers 311-314. The instructions further include transferring the substrate under vacuum conditions from the second plurality of process chambers 311-314 to the third plurality of process chambers 321-324, forming a blocking layer on the substrate in the third plurality of process chambers 321-324, transferring the substrate under vacuum conditions from the third plurality of process chambers 321-324 to the fourth plurality of process chambers 331-334, and depositing the material film on the substrate in the fourth plurality of process chambers 331-334.

Although not shown in FIG. 3, the processing system 3 may further include a plurality of process chambers for removing unwanted nuclei of the material film from the substrate, where the formation of the nuclei is due to imperfect deposition selectivity and the nuclei may be removed by etching to improve subsequent deposition selectivity.

Methods for selective film deposition using a surface pretreatment have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of processing a substrate, comprising:
providing a substrate having a first film and a second film, wherein the first and second films contain different materials; and
performing sequential dry processing steps at sub-atmospheric pressure, the steps including:
a) treating the substrate to remove a residue from the first and second films,
b) exposing the substrate to an oxygen-containing, gas to functionalize a surface of the first film,
c) exposing the substrate to a reactant gas that selectively forms a blocking layer on the first film or the second film, and
d) selectively depositing a material film on the first film or the second film not containing the blocking layer by exposing the substrate to a deposition gas.

2. The method of claim 1, further comprising:
e) removing the blocking layer from the substrate.

3. The method of claim 1, further comprising repeating steps a)-d) at least once.

4. The method of claim 1, wherein the first film contains a dielectric material.

5. The method of claim 1, wherein the second film contains a metal layer or a silicon layer.

6. The method of claim 1, wherein the metal layer contains Cu, Al, Ta, Ti, W, Ru, Co, Ni, or Mo.

7. The method of claim 1, wherein the blocking layer includes self-assembled monolayers (SAMs).

8. The method of claim 1, wherein the reactant gas includes a molecule that has a head group, a tail group, and a functional end group, and wherein the head group includes a thiol (R—SH), a silane, an alkene (R—C═C), an alkanoic acid (R—COOH), or a phosphonic acid (R—PO₃H3).

9. The method of claim 8, wherein the molecule includes perfluorodecyltrichlorosilane (CF₃(CF₂)₇CH₂CH₂SiCl₃), perfluorodecylmonochlorosilane, perfluorodecanethiol (CF₃(CF₂)₇CH₂CH₂SH), octadecyithiol, chlorodecyldimethylsilane (CH₃(CH₂)₈CH₂Si(CH₃)₂Cl), or tertbutyl(chloro)dimethylsilane ((CH₃)₃CSi(Cl)(CH₃)₂)).

10. The method of claim 1, wherein the material film includes a metal oxide film.

11. The method of claim 1, wherein the metal oxide film contains HfO₂, ZrO₂, or Al₂O₃.

12. The method of claim 1, wherein the exposing the substrate to the deposition gas forms nuclei of the material film on the first film or the second film containing the blocking layer, the method further comprising
removing, by etching, the nuclei of the material film.

13. The method of claim 1, further comprising:
wherein the material film includes a SiO₂ film deposited by exposing the substrate to a deposition gas contains a silanol gas selected from the group consisting of tris(tert-pentoxy) silanol, tris(tert-butoxy) silanol, and bis(tert-butoxy)(isopropoxy) silanol.

14. The method of claim 1, wherein the treating includes heat-treating the substrate, exposing the substrate to a cleaning gas containing forming gas, exposing the substrate to plasma-excited H₂ gas, or a combination thereof in any sequence.

15. The method of claim 1, wherein the exposing the substrate to an oxygen-containing gas includes exposing the substrate to an alcohol.

16. The method of claim 15, wherein the alcohol includes isopropyl alcohol or ethanol.

17. The method of claim 1, wherein steps a)-c) are performed without exposing the substrate to air at any time during or between the steps.

18. The method of claim 1, wherein steps a)-d) are performed without exposing the substrate to air at any time during or between the steps.

19. The method of claim 1, wherein the exposing the substrate to the deposition gas forms nuclei of the material film on the first film or second film containing the blocking layer, the method further comprising
removing, by etching, the nuclei of the material film, wherein steps a)-d) and the step of removing are performed without exposing the substrate to air at any time during or between any of the steps.

20. A processing system for integrated in-situ dry surface preparation and area selective film deposition, the system comprising:
a first plurality of process chambers for gaseous removal of a residue from a substrate;
a second plurality of process chambers for gaseous functionalization of a film on the substrate;
a third plurality of process chambers for gaseous formation of a blocking layer on the substrate;
a fourth plurality of process chambers for gaseous deposition of a material film on the substrate;
a vacuum transfer chamber connecting the first, second, third, and fourth plurality of process chambers; and
a controller including instructions for the integrated in-situ dry surface preparation and area selective film deposition, the instructions including:
removing the residue from the substrate in the first plurality of process chambers;
transferring the substrate under vacuum conditions from the first plurality of process chambers to the second plurality of process chambers;
functionalizing the film on the substrate in the second plurality of process chambers;
transferring the substrate under vacuum conditions from the second plurality of process chambers to the third plurality of process chambers;
forming a blocking layer on the substrate in the third plurality of process chambers;
transferring the substrate under vacuum conditions from the third plurality of process chambers to the fourth plurality of process chambers; and
depositing the material film on the substrate in the fourth plurality of process chambers.
